(19) United States
(12) Patent Application Publication
(10) Pub. No.: US 2026/0351316 A1
(43) Pub. Date: Nov. 5, 2026

(54) SEMICONDUCTOR DEVICES AND OPERATION METHODS THEREOF

(71) Applicant: Yangtze Memory Technologies Holding Co., Ltd., Wuhan (CN)

(72) Inventors: Jie He, Wuhan (CN); Weihua Shi, Wuhan (CN)

(21) Appl. No.: 19/366,150

(22) Filed: Oct. 22, 2025

(30) Foreign Application Priority Data
Apr. 30, 2025 (CN) 202510571415.2

(51) Int. Cl. G11C 16/26; G11C 16/04; G11C 16/10; G11C 16/24; G11C 16/32

(52) U.S. Cl. CPC G11C 16/26; G11C 16/0483; G11C 16/10; G11C 16/24; G11C 16/32

(57) ABSTRACT

An example device includes: a first semiconductor structure including a memory array; first bit lines coupled to a first memory cell; second bit lines coupled to a second memory cell; and a second semiconductor structure including a peripheral circuit coupled to the memory array and configured to: receive a first command, which comprises first data and first address information of the first bit lines coupled to the first memory cell, and the first command to instruct to store the first data in the first memory cell; and in response to the first command and in response to at least some of the first address information of the first bit lines corresponding to disabled bit lines, store a portion of the first data in the second memory cell, the portion of the first data corresponding to the at least some of the first address information of the first bit lines.

### CROSS-REFERENCE TO RELATED APPLICATION

This application claims priority to and the benefit of Chinese Patent Application 2025105714152, filed on Apr. 30, 2025, which is hereby incorporated by reference in its entirety.

### FIELD OF TECHNOLOGY

Examples of the present disclosure relate to the field of semiconductor technology, and in particular, to semiconductor devices and operation methods thereof.

### BACKGROUND

In a classical Von Neumann computing architecture, a memory is separated from a processor, and data is transmitted between the memory and the processor through a data bus. When executing a command, the processor first reads the data from the memory, and then writes the updated data back into the memory after processing is completed.

### BRIEF DESCRIPTION OF THE DRAWINGS

FIG. 1 is a schematic structural diagram of a semiconductor device provided by an example of the present disclosure.

FIG. 2 is a schematic diagram of a second semiconductor structure including a peripheral circuit provided by an example of the present disclosure.

FIG. 3 is a schematic cross-sectional diagram of a memory array including memory strings provided by an example of the present disclosure.

FIG. 4 is a schematic diagram of an example peripheral circuit provided by an example of the present disclosure.

FIG. 5 is a schematic structural diagram of a semiconductor device provided by another example of the present disclosure.

FIG. 6 is a schematic stereoscopic structural diagram of a semiconductor device corresponding to FIG. 5.

FIG. 7 is a schematic flowchart of an operation method of a semiconductor device provided by an example of the present disclosure.

FIG. 8 is a multiplexing logic block diagram of a data path in a semiconductor device provided by an example of the present disclosure.

FIG. 9 is a schematic diagram of an example electronic device having a semiconductor device according to an example of the present disclosure.

FIG. 10 is a schematic diagram of an example memory card having a semiconductor device according to an example of the present disclosure.

FIG. 11 is a schematic diagram of an example solid state drive having a semiconductor device according to an example of the present disclosure.

### DETAILED DESCRIPTION

The technical solutions in implementations of the present disclosure will be described below clearly and completely in conjunction with the implementations and the drawings of the present disclosure. Implementations described are only part, but not all, of the implementations of the present disclosure. All other implementations obtained by those of ordinary skills in the art based on the implementations in the present disclosure without creative work shall fall within the scope of protection of the present disclosure.

In the following descriptions, a lot of details are given in order to provide a thorough understanding of the present disclosure. However, it is apparent to those skilled in the art that the present disclosure may be implemented without one or more of these details. In other examples, in order to avoid confusion with the present disclosure, some technical features well-known in the field are not described. That is, not all the features of the actual examples are described here, and well-known functions and structures are not described in detail.

In the drawings, the sizes of a layer, a region, and an element and their relative sizes may be exaggerated for clarity. Like reference numerals denote like elements throughout the specification.

It should be understood that when an element or a layer is referred to as being “on”, “adjacent to”, “connected to”, or “coupled to” other elements or layers, it may be directly on, adjacent to, connected to, or coupled to the other elements or layers, or intervening elements or layers may be present. In contrast, when an element is referred to as being “directly on”, “immediately adjacent to”, “directly connected to”, or “directly coupled to” other elements or layers, no intervening elements or layers are present. It should be understood that, although terms first, second, third and the like may be used to describe various elements, components, regions, layers and/or parts, these elements, components, regions, layers and/or parts should not be limited by these terms. These terms are only used to distinguish one element, component, region, layer or part from another element, component, region, layer or part. Thus, a first element, component, region, layer or part discussed below may be represented as a second element, component, region, layer or part, without departing from the teachings of the present disclosure. However, when the second element, component, region, layer or part is discussed, it does not mean that the first element, component, region, layer or part is necessarily present in the present disclosure.

Spatially relative terms, such as “beneath”, “below”, “lower”, “under”, “over”, “upper”, etc., may be used here for ease of description to describe the relationship between one element or feature and other elements or features as illustrated in the figures. It should be understood that the spatially relative terms are intended to further encompass different orientations of a device in use or operation in addition to the orientation depicted in the figures. For example, if the device in the drawings is flipped, then the elements or the features described as “below” or “under” or “beneath” other elements may be oriented “on” the other elements or features. Thus, the example terms “below” and “beneath” may comprise both upper and lower orientations. The device may be orientated otherwise (rotated by 90 degrees or other orientations), and the spatially descriptive words used here are interpreted accordingly.

The terms used here are only intended to describe the specific examples, and are not used as limitations to the present disclosure. As used here, unless otherwise indicated expressly in the context, “a”, “an” and “the” in a singular form are also intended to comprise a plural form. It should also be understood that terms “consist of” and/or “comprise”, when used in this specification, determine the presence of the described features, integers, steps, operations, elements and/or components, but do not preclude the presence or addition of one or more other features, integers, steps, operations, elements, components, and/or groups. As used here, a term “and/or” comprises any and all combinations of related items listed.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

In order to understand the present disclosure thoroughly, detailed operations and detailed structures will be proposed in the following description to set forth the technical solution of the present disclosure. The detailed descriptions of the preferred examples of the present disclosure are as follows. However, the present disclosure may also have other implementations in addition to these detailed descriptions.

The semiconductor device according to the examples of the present disclosure may be at least part of a final device structure. Here, the final device may include, but is not limited to, a NAND flash memory, a vertical NAND flash memory, a NOR flash memory, a dynamic random access memory (DRAM), a ferroelectric random access memory (FRAM), a magnetoresistive random access memory (MRAM), a phase change random access memory (PCRAM), a resistive random access memory (RRAM), a nano random access memory (NRAM), etc. For ease of understanding, a NAND type memory is taken as an example for description below. However, it should be noted that the description of the NAND type memory in the following examples is only used to illustrate the present disclosure, and is not used to limit the scope of the present disclosure.

It should be understood that in a classical Von Neumann computing architecture, a memory is separate from a processor, and data is transmitted through a data bus between the memory and the processor. When executing a command, the processor first reads the data from the memory, and then writes the updated data back into the memory after processing is completed, the frequent data migration brings huge power consumption and time overheads. In addition, since the memory bandwidth is limited, the processing speed of the processor is limited by the access speed of the memory, which greatly affects the computing performance. With the rise of applications such as big data and artificial intelligence, massive data processing makes the bottleneck of the Von Neumann computing architecture more and more prominent. In order to solve the bottleneck of the classic Von Neumann computing architecture, a computing-in-memory chip architecture emerges, and the basic idea is to embed a computing function in the memory and directly use the memory to perform logic computation, thereby reducing data transmission amount and transmission distance between the memory and the processor, reducing power consumption, and improving computing performance, so that a computing system with high computing power, high bandwidth and high energy efficiency is expected to be constructed.

In practical applications, the memory may have a certain bit line failure rate in process production, and it may employ a redundant replacement mechanism to replace a failed bit line with a redundant bit line, so as to ensure the utilization rate of the memory. However, in a three-dimensional computing-in-memory chip architecture, how to implement the redundant bit line replacement mechanism in the memory and the processor becomes an urgent problem to be solved.

The following describes in detail, with reference to the accompanying drawings, a NAND flash memory, a computing-in-memory chip having a NAND flash memory, and how to implement replacement of redundant bit lines by a computing-in-memory chip having a NAND flash memory provided by examples of the present disclosure.

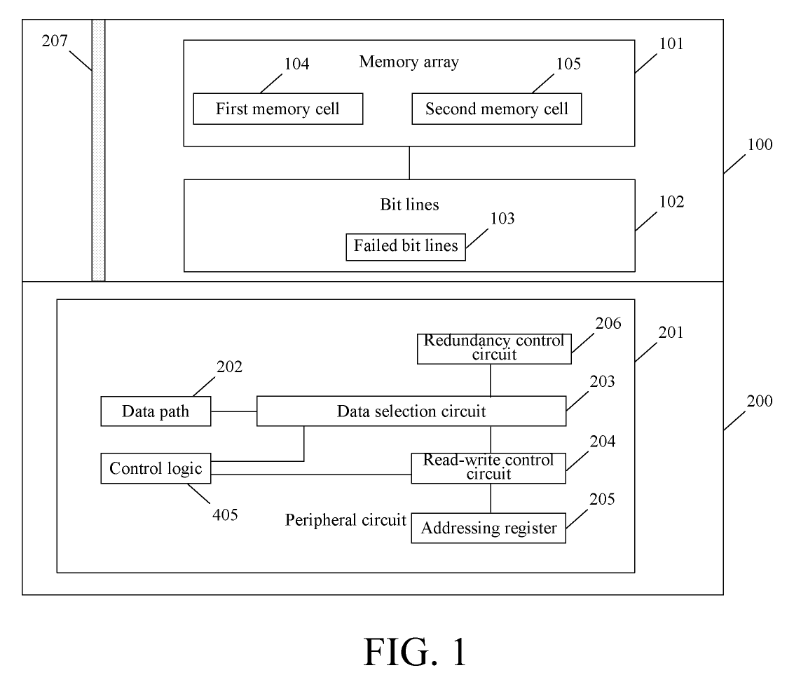

Before introducing the semiconductor device illustrated in FIG. 1, various directions that may be used in the following description are defined. The stacking direction of a first semiconductor structure and a second semiconductor structure in the semiconductor device is defined as a first direction (e.g., a Z-axis direction) hereinafter. A second direction (e.g., an X-axis direction) and a third direction ( e.g., a Y-axis direction) intersecting with each other are defined in a plane perpendicular to the Z-axis direction. In some examples, the X-axis direction, the Y-axis direction, and the Z-axis direction may be pairwise perpendicular to each other.

In a first aspect, an example of the present disclosure provides a semiconductor device, comprising: a first semiconductor structure comprising a memory array and a plurality of bit lines coupled to the memory array, the memory array comprising a first memory cell and a second memory cell; and a second semiconductor structure comprising a peripheral circuit coupled to the memory array and configured to: receive a first command, which comprises first data and address information of bit lines coupled to the first memory cell, and instructs to store the first data in the first memory cell; and in response to the first command, when at least part of address information of the bit lines in the address information of the bit lines coupled to the first memory cell is the same as address information of failed bit lines (e.g., disabled bit lines) among the plurality of bit lines, store data in the first data corresponding to at least part of the address information of the bit lines into the second memory cell. In this way, when there are failed bit lines (e.g., disabled bit lines) among the bit lines coupled to the first memory cell, it will be instructed that at least part of the data stored in the first memory cell is transferred to the second memory cell through redundancy replacement mechanism, so that the semiconductor structure with part of bit lines failed is continuously used, and the utilization rate and the final yield of the semiconductor device are improved.

Referring to FIG. 1, FIG. 1 is a schematic structural diagram of a semiconductor device provided by an example of the present disclosure, wherein the semiconductor device comprises a first semiconductor structure 100 and a second semiconductor structure 200. The first semiconductor structure 100 and the second semiconductor structure 200 are stacked on each other along the Z-axis direction, so that the overall size of the semiconductor device can be reduced, and the memory density can be increased. In some specific examples, the first semiconductor structure 100 and the second semiconductor structure 200 may be bonded by hybrid bonding, transfer bonding, anodic bonding, fusion bonding, adhesive bonding, eutectic bonding, etc. In an example, the first semiconductor structure 100 and the second semiconductor structure 200 may be formed on different substrates in parallel, for example, the first semiconductor structure 100 is formed on the first substrate, the second semiconductor structure 200 is formed on the second substrate, and then they are stacked on each other using various suitable bonding techniques such as hybrid bonding.

Here, the first semiconductor structure 100 comprises a memory array 101 and a plurality of bit lines 102 coupled to the memory array 101, wherein the memory array 101 comprises a first memory cell 104 and a second memory cell 105, and both the first memory cell 104 and the second memory cell 105 may be configured to store data. The second semiconductor structure 200 comprises a peripheral circuit 201 coupled to the memory array 101. It should be understood that the peripheral circuit 201 and the memory array 101 may be coupled in any suitable manner, such as hybrid bonding, transfer bonding, anodic bonding, fusion bonding, adhesive bonding, eutectic bonding, etc.

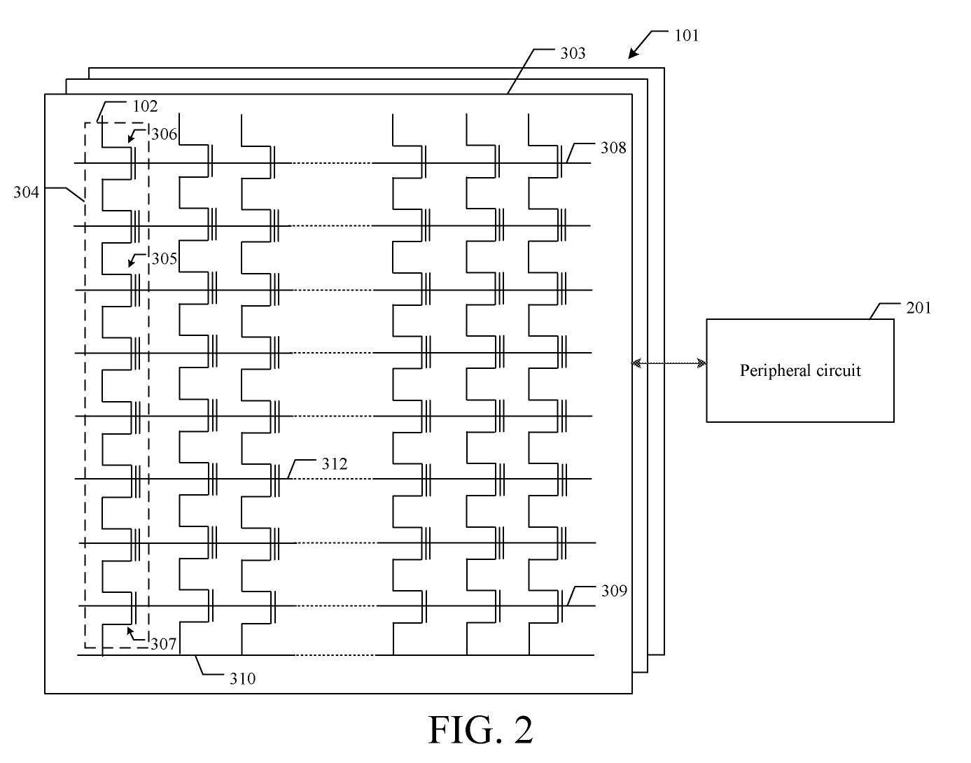

In some specific examples, the memory array 101 may comprise a plurality of planes, each plane may include a plurality of banks, each bank may include a plurality of blocks, each block may include a plurality of memory strings, each memory string may include a plurality of memory cells connected in series. In an example, referring to FIG. 2, the memory array 101 includes a plurality of blocks 303, each block 303 includes a plurality of memory strings 304, and each memory string 304 includes a plurality of memory cells 305 coupled in series and stacked vertically. Each memory cell 305 may hold a continuous analog value, e.g., voltage or charge, depending on the number of electrons trapped within the region of the memory cell 305. Each memory cell 305 may be a floating gate type memory cell including a floating gate transistor or a charge trapping type memory cell including a charge trapping transistor. In an example of the present disclosure, the plurality of memory cells 305 in the memory array 101 may be divided into a first memory cell 104 and a second memory cell 105. In some specific examples, the memory array may include a plurality of NAND memory cells; the semiconductor device may include a three-dimensional NAND type memory.

In some examples, each memory cell 305 is a single level cell (SLC) that has two possible memory states and thus can store one bit of data. For example, a first memory state “0” may correspond to a first voltage range and a second memory state “1” may correspond to a second voltage range. In some examples, each memory cell 305 is a multi-level cell capable of storing more than a single bit of data in four or more than four memory states, e.g., a multi-level cell (MLC) storing two bits per cell, a triple level cell (TLC) storing three bits per cell, or a quad-level cell (QLC) storing four bits per cell.

As shown in FIG. 2, each memory string 304 may include a bottom select transistor (BSG) 307 at its source terminal and a top select transistor (TSG) 306 at its drain terminal. The bottom select transistor 307 and the top select transistor 306 may be configured to activate the selected memory string 304 during read and program operations. In some examples, source terminals of memory strings 304 in the same block 303 may be coupled through a common source line (CSL) 310. In other words, all the memory strings 304 in the same block 303 have an array common source (ACS). According to some examples, the top select transistor 306 of each memory string 304 is coupled to a respective bit line 102 from which data may be read or written via an output bus (not shown). In some implementations, each memory string 304 is configured to be selected or deselected by applying a select voltage (e.g., a voltage above a threshold voltage of the top select transistor 306) or a deselect voltage (e.g., 0V) to a respective top select transistor 306 through one or more top select lines (TSL) 308 and/or by applying a select voltage (e.g., a voltage above a threshold voltage of the bottom select transistor 307) or deselect voltage (e.g., 0V) to a respective bottom select transistor 307 through one or more bottom select lines (BSL) 309.

As shown in FIG. 2, the memory string 304 may be organized into a plurality of blocks 303, each of which may have a common source line 310. In some examples, each block 303 is a basic data unit for an erase operation, e.g., all the memory cells 305 on the same block 303 are erased simultaneously. To erase memory cells 305 in a selected block, a common source line 310 coupled to the selected memory block and unselected blocks on the same plane as the selected memory block may be biased with an erase voltage. It should be understood that in some examples, the erase operation may be performed at a half block level, at a quarter block level, or at a level having any suitable number of blocks or any suitable fraction of block. The memory cells 305 in adjacent memory strings 304 may be coupled through a word line (WL) 312 that selects which row of memory cells 305 is affected by a read or program operation.

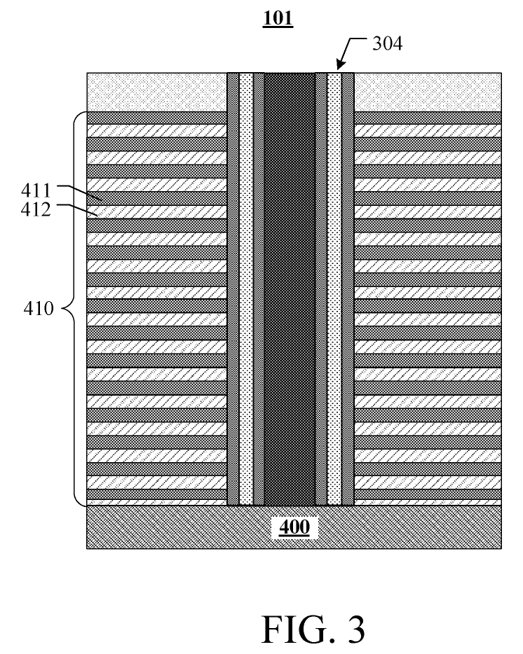

FIG. 3 is a schematic cross-sectional diagram of an example memory array including memory strings provided by an example of the present disclosure. As shown in FIG. 3, the memory array 101 may include a stack structure 410, which includes a plurality of gate layers 411 and a plurality of insulating layers 412 alternately stacked in sequence, and a channel structure vertically extending through the gate layers 411 and the insulating layers 412, wherein the channel structure is coupled to each gate layer 411 to form a memory cell, and the channel structure is coupled to the plurality of gate layers in the stack structure 410 to form a memory string 304. The gate layers 411 and the insulating layers 412 may be alternately stacked, and two adjacent gate layers 411 are separated by one insulating layer 412.

The constituent material of the gate layer 411 may include a conductive material. The conductive material includes, but is not limited to, tungsten (W), cobalt (Co), copper (Cu), aluminum (Al), polysilicon, doped silicon, silicide, or any combination thereof. In some implementations, each gate layer 411 includes a metal layer, such as a tungsten layer. In some implementations, each gate layer 411 includes a doped polysilicon layer. Each gate layer 411 may include a control gate surrounding the memory cell. The gate layer 411 at the top of the stack structure 410 may extend laterally as a top select gate line, the gate layer 411 at the bottom of the stack structure 410 may extend laterally as a bottom select gate line, and the gate layers 411 extending laterally between the top select gate line and the bottom select gate line may act as word line layers. The top select gate line is configured for forming the top select transistor 306 and the bottom select gate line is configured for forming the bottom select transistor 307.

In some examples, the stack structure 410 may be disposed on a substrate 400. The substrate 400 may include silicon (e.g., monocrystalline silicon), silicon germanium (SiGe), gallium arsenide (GaAs), germanium (Ge), silicon-on-insulator (SOI), germanium-on-insulator (GOI), or any other suitable material. In other examples, the semiconductor device may not include a substrate.

In some examples, the memory string 304 includes a channel structure that extends vertically through the stack structure 410. In some implementations, the channel structure includes a channel hole filled with semiconductor material(s) (e.g., as a semiconductor channel) and dielectric material(s) (e.g., as a memory film). In some implementations, the semiconductor channel includes silicon, e.g., polysilicon. In some implementations, the memory film is a composite dielectric layer including a tunneling layer, a storage layer (also referred to as a “charge trapping/storage layer”), and a blocking layer. The channel structure may have a cylindrical shape (e.g., a pillar shape). According to some implementations, the semiconductor channel, the tunneling layer, the storage layer, and the blocking layer are arranged radially from a center of the pillar toward an outer surface of the pillar in this order. The tunneling layer may include silicon oxide, silicon oxynitride, or any combination thereof. The storage layer may include silicon nitride, silicon oxynitride, or any combination thereof. The blocking layer may include silicon oxide, silicon oxynitride, high-k dielectric, or any combination thereof. In one example, the memory film may include a composite layer of silicon oxide/silicon oxynitride/silicon oxide (ONO).

In some examples, referring back to FIG. 2, the peripheral circuit 201 may include any suitable analog, digital, and mixed signal circuit for implementing operations on memory array 101 by applying voltage signals and/or current signals to and sensing voltage signals and/or current signals from each target memory cell through the bit line 102, the word line 312, the common source line 310, the bottom select line 309, and the top select line 308. The peripheral circuit 201 may include various types of peripheral circuits formed using metal-oxide-semiconductor technology.

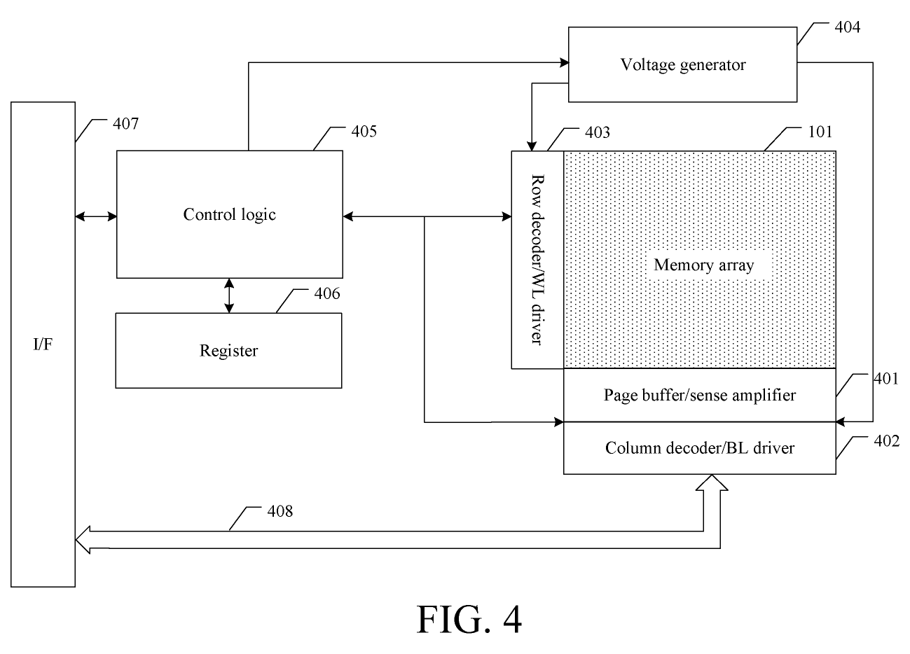

Referring to FIG. 4, FIG. 4 illustrates some example peripheral circuits including a page buffer/sense amplifier 401, a column decoder/bit line driver 402, a row decoder/word line driver 403, a voltage generator 404, a control logic 405, a register 406, a flash interface I/F 407, and a data bus 408. It should be understood that in some examples, the peripheral circuit may further include additional peripheral circuits not shown in FIG. 4.

The page buffer/sense amplifier 401 may be configured to read data from and program (write) data into the memory array 101 according to control signals from the control logic 405. In one example, the page buffer/sense amplifier 401 may store one page of program data (write data) to be programmed into the memory array 101. In another example, the page buffer/sense amplifier 401 may perform a program verify operation to ensure that the data has been properly programmed into the memory cell coupled to the selected word line. In yet another example, the page buffer/sense amplifier 401 may also sense a low power signal from the bit line representing a data bit stored in the memory cell, and amplify small voltage swing to identifiable logic level in a read operation. The column decoder/bit line driver 402 may be configured to be controlled by the control logic 405 and select one or more memory cell strings by applying a bit line voltage generated from the voltage generator 404.

The row decoder/word line driver 403 may be configured to be controlled by the control logic 405 and select/deselect the blocks of the memory array 101 and select/deselect the word lines of the blocks. The row decoder/word line driver 403 may further be configured to drive the word lines using the word line voltage generated from the voltage generator 404. In some implementations, the row decoder/word line driver 403 may further select/deselect and drive the bottom select line and the top select line. As described in detail below, the row decoder/word line driver 403 is configured to perform a program operation on the memory cells coupled to the selected word line(s). The voltage generator 404 may be configured to be controlled by the control logic 405 and generate a word line voltage (e.g., a read voltage, a program voltage, a pass voltage, a local voltage, a verify voltage, etc.), a bit line voltage, and a source line voltage to be supplied to the memory array 101.

The control logic 405 may be coupled to each peripheral circuit described above and configured to control operation of each peripheral circuit. The register 406 may be coupled to the control logic 405 and include a status register, a command register, and an address register for storing status information, command operation code (OP code), and command address for controlling operation of each peripheral circuit. The flash interface 407 may be coupled to the control logic 405 and act as a control buffer to buffer and relay control commands received from a host-side device (not shown) to the control logic 405 and buffer and relay status information received from the control logic 405 to a memory controller. The flash interface 407 may further be coupled to the column decoder/bit line driver 402 via the data bus 408 and act as a data input/output (I/O) interface and a data buffer to buffer and relay data to the memory array 101 or relay or buffer data from the memory array 101.

In an example of the present disclosure, referring back to FIG. 1, the peripheral circuit 201 further comprises: a data path 202, a data selection circuit 203, a read-write control circuit 204, an addressing register (CAM) 205, and a redundancy control circuit 206. The data path 202 is coupled to the data selection circuit 203, and the data path 202 may be configured to be controlled by the control logic 405 to transmit data; the data selection circuit 203 may be further coupled to the control logic 405, the read-write control circuit 204, and the memory array 101, and may be configured to be controlled by the control logic 405 to select to read/write data from the memory array 101 or the addressing register 205; the read-write control circuit 204 may be coupled to the data selection circuit 203 and the addressing register 205, and may be configured to be controlled by the control logic 405 to perform a read operation or a write operation; the addressing register 205 may be configured to be controlled by the control logic 405 to store address information or other data; and the redundancy control circuit 206 may be coupled to the data selection circuit 203 and the memory array 101, and may be configured to be controlled by the control logic 405 to select an adapted transmission interface to transmit data in beats.

In some examples, the peripheral circuit 201 is configured to: before receiving a first command CMD1, receive and respond to a third command CMD3, which instructs to perform a failure test on the plurality of bit lines 102 to determine whether there are failed bit lines 103 (e.g., disabled bit lines) among the plurality of bit lines 102. When there are failed bit lines 103 among the plurality of bit lines 102, address information of the failed bit lines 103 is obtained. Here, the method for performing the failure test on the plurality of bit lines comprises, but is not limited to, voltage contrast imaging, bias voltage auxiliary detection, hot spot analysis, etc. The failed bit lines may be understood as bit lines that cannot work normally due to manufacturing defects, short circuits, electric leakage or other faults, and is usually represented as abnormal voltage contrast, electric leakage or short circuit phenomenon, or physical structure damage, etc.

It should be understood that, when there is no failed bit line 103 among the plurality of bit lines 102, that is, all the bit lines 102 are bit lines that can work normally, the first data is directly stored into the first memory cell according to the instruction of the first command without performing the above mentioned redundant replacement operation. When there are failed bit lines 103 among the plurality of bit lines 102, the redundant replacement operation needs to be performed.

In some examples, when it is determined that there are failed bit lines 103 among the plurality of bit lines 102, the peripheral circuit 201 is further configured to: receive and respond to a fourth command CMD4 to store address information of the failed bit lines into the addressing register 205.

In some examples, the peripheral circuit 201 is further configured to: receive a first command CMD1 including first data (data1) and address information of the bit lines coupled to the first memory cell 104; the first command CMD1 instructs to store the first data (data1) into the first memory cell 104. Here, the first command CMD1 is a write command.

The peripheral circuit 201 is further configured to: in response to the first command CMD1, compare the address information of the bit lines coupled to the first memory cell 104 with the address information of the failed bit lines stored into the addressing register 205, and determine the storage location of the first data according to the comparison result. When all the address information of the bit lines coupled to the first memory cell 104 is the same as the address information of the failed bit lines, it is instructed that all the bit lines coupled to the first memory cell 104 are failed bit lines, and at this point, all the first data (data1) is transferred to the second memory cell 105, so as to implement redundant replacement of all the failed bit lines with the bit lines coupled to the second memory cell 105. Here, after the redundant replacement of all the failed bit lines is performed, the address information of the bit lines coupled to the second memory cell 105 is stored into the addressing register 205, and forms a first mapping relationship with the address information of corresponding failed bit lines.

When part of address information of the bit lines coupled to the first memory cell 104 is the same as the address information of the failed bit lines 103, it is instructed that part of the bit lines coupled to the first memory cell 104 are failed bit lines. At this point, the first data (data1) is divided into two parts, such as second data (data2) and third data (data3), the second data (data2) is data corresponding to the failed bit lines among the bit lines coupled to the first memory cell 104, and the third data (data3) is data corresponding to normal bit lines among the bit lines coupled to the first memory cell 104. The second data (data2) is stored into the second memory cell 105, and the third data (data3) is stored into the first memory cell 104, so as to implement redundant replacement of part of the failed bit lines with bit lines coupled to the second memory cell 105. Here, after the redundant replacement of the part of the failed bit lines is performed, the address information of the bit lines coupled to the second memory cell 105 is stored into the addressing register 205, and forms a second mapping relationship with the address information of corresponding failed bit lines.

It should be understood that in the first mapping relationship and the second mapping relationship, the number of bit lines coupled to the second memory cell 105 is different.

In an example of the present disclosure, the number of failed bit lines 103 is less than or equal to the number of bit lines coupled to the second memory cell 105, so that the integrity of the data can be ensured. In an example, the addressing register 205 can store 11 entries of address information (ca<10:0>) of failed bit lines, and in the address information of the bit lines coupled to the first memory cell 104, the number of entries of address information of the bit lines that are redundantly replaced needs to be less than or equal to 11. In this way, the addressing register 205 can completely store its corresponding address information to ensure the integrity of the data.

It should be noted that, when all the address information of the bit lines coupled to the first memory cell 104 is different from the address information of the failed bit lines, it is instructed that all the bit lines coupled to the first memory cell 104 are normal bit lines. At this point, all the first data is stored into the first memory cell 104, and no redundant replacement is required.

In some examples, during the process of responding to the first command CMD1, the first data is transmitted to the data selection circuit 203 through the data path 202, and the data selection circuit 203 selects to store all the first data into the first memory cell 104, or store part of the first data into the first memory cell 104 and another part of the first data in the second memory cell 105, or store all the first data into the second memory cell 105 according to the comparison result output by the control logic 405. In this way, the write operation of the first data is completed.

For ease of understanding, in the following examples, it is taken as an example for description that there are failed bit lines among the plurality of bit lines, that is, part of data (e.g., the second data) in the first data is stored into the second memory cell 105, and another part of data ( e.g., the third data) is stored into the first memory cell 104. In this case, part of the failed bit lines are redundantly replaced with the bit lines of the second memory cell 105.

In some examples, referring to FIG. 1, the redundancy control circuit 206 is located between the data selection circuit 203 and the memory array 101, and the redundancy control circuit 206 is configured to: gate the second data to transmission interface such as redundant transmission interface Red-out<10:0> coupled to the second memory cell in beats.

In some examples, referring to FIG. 1, when there are multiple entries of address information of the bit lines coupled to the second memory cell 105, the read-write control circuit 204 is configured to: generate a plurality of write clock signals and a plurality of data write signals in response to the first command CMD1. The data selection circuit 203 is configured to: sequentially store the second data into the second memory cell and the third data into the first memory cell based on the plurality of write clock signals and the plurality of data write signals.

In some examples, the peripheral circuit 201 is further configured to: receive a second command CMD2, which is a read command, and instructs to read the first data. The peripheral circuit 201 is further configured to: in response to the second command CMD2, feed back the address information of the bit lines coupled to the second memory cell 105, the second data and the third data.

In some examples, the control logic 405 receives and responds to the second command CMD2 to generate a control signal; based on the control signal, obtains the address information of the bit lines coupled to the second memory cell 105 from the addressing register 205, obtains the third data from the first memory cell, and obtains the second data from the second memory cell. The read-write control circuit 204 is configured to generate a plurality of read clock signals and a plurality of data read signals during the process of responding to the second command CMD2. The data selection circuit 203 multiplexes the second data, the third data and the address information of the failed bit lines onto the data path 202 based on the plurality of read clock signals and the plurality of data read signals, for example, multiplexes the second data, the third data and the address information of the failed bit lines onto redundant transmission interface such as Red-out<10:0> of the data path 202 in beats. The data path 202 is configured to transmit the address information of the bit lines coupled to the second memory cell, the second data and the third data during the process of responding to the second command CMD2.

In the above example, during the process of responding to the second command CMD2 (that is, performing the read operation), the address information of the bit lines coupled to the second memory cell 105 may be multiplexed to the data path 202, that is, the transmission path of the address information of the bit lines coupled to the second memory cell 105 during the read operation is multiplexed with the transmission path of the data during the read and write operation. In this way, there is no need to add the transmission path of address information, and the process difficulty and manufacturing cost are reduced

It should be noted that when all the first memory cell 104 is redundantly replaced with the second memory cell 105, all the first data is stored into the second memory cell 105. At this point, in response to the second command CMD2, the peripheral circuit is configured to feed back the address information of the bit lines coupled to the second memory cell and the first data. Likewise, the address information of the bit lines coupled to the second memory cell multiplexes the transmission path of the first data (data path 202) without adding a new transmission path, thereby reducing manufacturing cost.

In some examples, referring to FIG. 1, the first semiconductor structure 100 further comprises a connection structure 207 extending through the memory array 101, wherein one end of the connection structure 207 is connected to the peripheral circuit 201; the connection structure 207 is configured to transmit a fourth command CMD4 of the first command CMD1, the second command CMD2, and the third command CMD3. The connection structure 207 may be formed by through-silicon via (TSV) technology. It should be understood that the connection structure 207 herein extends through the level or position where the memory array 101 is located, does not extend through the memory cells in the memory array, and does not damage the memory cells.

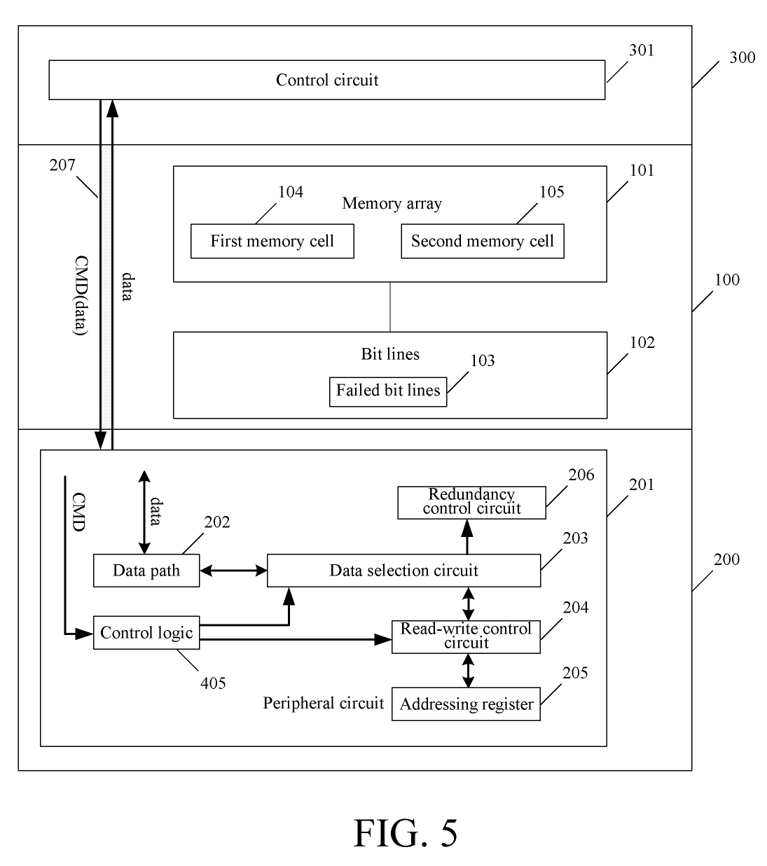

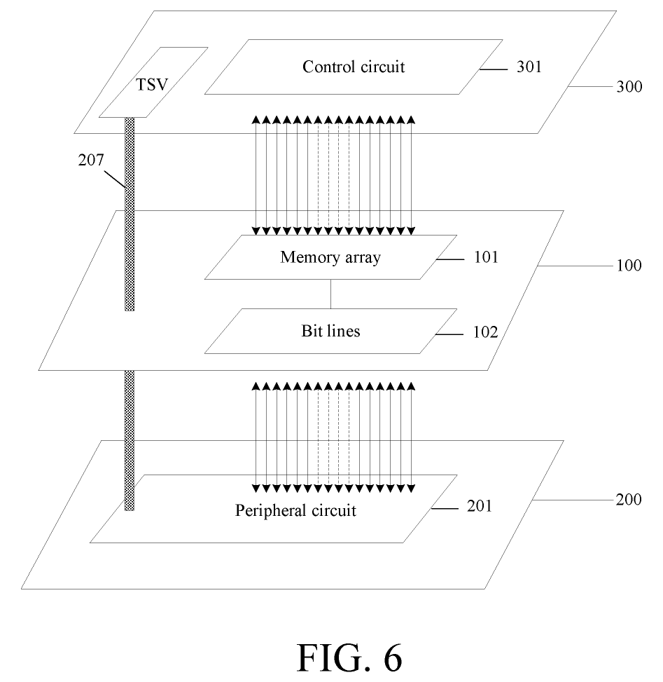

In a second aspect, the present disclosure provides another semiconductor device, referring to FIGS. 5, and 6, 5 is a schematic structural diagram of another semiconductor device, and FIG. 6 is a schematic stereoscopic structural diagram of the semiconductor device corresponding to FIG. 5. It should be noted that in FIG. 6, transmission paths of different signals are shown by way of example using solid lines and dashed lines, wherein the solid lines are used to represent transmission paths of data corresponding to normal bit lines, and the dashed lines are used to represent transmission paths of data corresponding to redundantly replaced bit lines. However, it should be understood that the above signal transmission paths are merely used to illustratively describe the present disclosure, and are not intended to limit the scope of the present disclosure.

As shown in FIGS. 5 and 6 the semiconductor device comprises: a first semiconductor structure 100 comprising a memory array 101 and a plurality of bit lines 102 coupled to the memory array 101, the memory array 101 comprising a first memory cell 104 and a second memory cell 105; a second semiconductor structure 200 comprising a peripheral circuit 201; and a third semiconductor structure 300 comprising a control circuit 301, wherein the peripheral circuit 201 is coupled to the memory array 101 and the control circuit 301, respectively.

As shown in FIG. 5, the first semiconductor structure 100, the second semiconductor structure 200, and the third semiconductor structure 300 may be stacked on each other along the Z-axis direction, so that the overall size of the semiconductor device can be reduced and the memory density can be increased. Here, the first semiconductor structure 100 is located between the second semiconductor structure 200 and the third semiconductor structure 300; in other examples, they may also be stacked in other arrangements, such as the second semiconductor structure 200 being located between the first semiconductor structure 100 and the third semiconductor structure 300, etc., which is not limited in the present disclosure.

In some specific examples, the first semiconductor structure 100, the second semiconductor structure 200, and the third semiconductor structure 300 may be formed in parallel on different substrates, for example, the first semiconductor structure 100 is formed on the first substrate, the second semiconductor structure 200 is formed on the second substrate, the third semiconductor structure 300 is formed on the third substrate, and then they are stacked on each other using means such as hybrid bonding, transfer bonding, anodic bonding, fusion bonding, adhesive bonding, and eutectic bonding, etc.

In some examples, the semiconductor device further comprises a connection structure 207 extending through the memory array 101 and respectively connected to the peripheral circuit 201 and the control circuit 301, so as to realize the coupling of the peripheral circuit 201 and the control circuit 301, thereby shortening the distance between the peripheral circuit 201 and the control circuit 301 and reducing the signal delay. Here, the connection structure 207 is, for example, a TSV structure. The control circuit 301 is configured to send commands, and the connection structure 207 is configured to transmit the commands. The control circuit 301 may also be coupled to an external device such as a host.

In some examples, referring to FIG. 5, the control circuit 301 is further configured to: send a third command CMD3 instructing to test a plurality of bit lines in the memory array.

The peripheral circuit 201 is further configured to: receive and respond to the third command CMD3, test the plurality of bit lines, and obtain address information of the failed bit lines. The failure test method comprises, but is not limited to, voltage contrast imaging, bias voltage auxiliary detection, and hot spot analysis, etc. A failed bit line may be understood as a bit line that cannot work normally due to manufacturing defects, short circuits, electric leakage or other faults, and is usually represented as abnormal voltage contrast, electric leakage or short circuit phenomenon, or physical structure damage, etc.

In some examples, the control circuit 301 is further configured to: send a fourth command CMD4 instructing to store the address information of the failed bit lines into the addressing register 205 of the peripheral circuit.

The peripheral circuit 201 is further configured to: receive and respond to the fourth command CMD4 to store the address information of the failed bit lines into the addressing register 205.

In some examples, the control circuit 301 is configured to: send a first command CMD1, which is a write command. The first command CMD1 includes first data and address information of the bit lines coupled to the first memory cell 104; the first command CMD1 instructs to store the first data into the first memory cell 104.

The peripheral circuit 201 is configured to: receive and respond to the first command CMD1, when at least part of address information of the bit lines in the address information of the bit lines coupled to the first memory cell 104 is the same as the address information of the failed bit lines 103 among the plurality of bit lines, store data in the first data corresponding to the at least part of the address information of the bit lines into the second memory cell 105. In this way, when there are failed bit lines among the bit lines coupled to the first memory cell, it will be instructed that at least part of the data stored into the first memory cell is transferred to the second memory cell through redundancy replacement mechanism, so that the semiconductor structure with part of bit lines failed is continuously used, and the utilization rate and the final yield of the semiconductor device are improved.

In an example, the peripheral circuit 201 is further configured to compare the address information of the bit lines coupled to the first memory cell 104 with the address information of the failed bit lines stored into the addressing register 205, and determine the storage location of the first data according to the comparison result. When the address information of the bit lines coupled to the first memory cell 104 is all the same as address information of the failed bit lines, all the first data is transferred to the second memory cell 105, to implement redundant replacement of all the failed bit lines with the bit lines coupled to the second memory cell 105. Here, after all redundancy replacement is performed, the address information of the bit lines coupled to the second memory cell 105 is stored into the addressing register 205, and forms a first mapping relationship with the address information of corresponding failed bit lines. When part of the address information of the bit lines coupled to the first memory cell 104 is the same as the address information of the failed bit line 103s, data (e.g., the second data) in the first data corresponding to the failed bit lines is stored into the second memory cell 105, and the remaining data (e.g., the third data) is stored into the first memory cell 104, so as to implement redundant replacement of part of the failed bit lines with the bit lines coupled to the second memory cell 105. Here, after partial redundancy replacement is performed, the address information of the bit lines coupled to the second memory cell 105 is stored into the addressing register 205, and forms a second mapping relationship with the address information of corresponding failed bit lines. In this way, the write operation of the first data is completed.

During the process of responding to the first command CMD1, the data path 202 is configured to transmit the first data; the control logic 405 is configured to generate a control signal based on the first command CMD1; and based on the control signal, the data selection circuit 203 is configured to select to store all the first data into the first memory cell 104, or store part of the first data into the first memory cell 104 and store another part of the first data into the second memory cell 105, or store all the first data into the second memory cell 105 according to the comparison result output by the control logic 405.

Here and below, it is taken as an example for the description that part of the first data is stored into the first memory cell 104 and another part of the first data is stored into the second memory cell 105.

When the second data needs to be stored into the second memory cell 105, the redundancy control circuit 206 is configured to: gate the second data to transmission interface such as redundant transmission interface (Red-out<10:0 >) coupled to the second memory cell in beats.

During this time, the read-write control circuit 204 is configured to generate a plurality of write clock signals and a plurality of data write signals. The data selection circuit 203 is configured to: sequentially store the second data into the first memory cell 104 and the third data into the second memory cell 105 based on the plurality of write clock signals and the plurality of data write signals.

In some examples, referring to FIG. 5, the control circuit 301 is further configured to: send a second command CMD2, which is a read command. The second command CMD2 is configured to instruct to read the first data.

In some examples, the peripheral circuit 201 is configured to receive and respond to the second command CMD2 to send the second data stored in the second memory cell 105, the third data stored in the first memory cell, and the address information of the bit lines coupled to the second memory cell stored in the addressing register to the control circuit 301 through the data path 202.

After receiving the address information of the bit lines coupled to the second memory cell, the second data and the third data, the control circuit 301 processes the second data and the third data based on the address information of the bit lines coupled to the second memory cell to obtain the first data. For example, based on the comparison between the address information of the bit lines coupled to the second memory cell 105 and the address information of the bit lines coupled to the first memory cell 104, the specific positions of the second data and the third data are determined to obtain the complete first data.

During the process of responding to the second command CMD2, the control logic 405 is configured to generate a control signal based on the second command. The data selection circuit 203 is configured to obtain the third data from the first memory cell, obtain the second data from the second memory cell, and obtain the address information of the bit lines coupled to the second memory cell from the addressing register based on the control signal.

During this time, the read-write control circuit 204 is configured to generate a plurality of read clock signals and a plurality of data read signals. The data selection circuit 203 is configured to sequentially multiplex the second data, the third data, and the address information of the bit lines coupled to the second memory cell onto the data path 202 based on the plurality of read clock signals and the plurality of data read signals, for example, multiplex them onto the redundant transmission interface of data path 202 such as Red-out<10:0>. The data path 202 is configured to transmit the address information of the bit lines coupled to the second memory cell, the second data and the third data during the process of responding to the second command CMD2.

In the examples of the present disclosure, on the one hand, by transmitting the address information of the bit lines coupled to the second memory cell to the control circuit, implementing the share of redundant replacement information between the peripheral circuit and the control circuit, redundant replacement mechanism may also be implemented among the control circuit, the peripheral circuit and the memory array when they are bonded and stacked. On the other hand, by multiplexing the data path when transmitting the address information of the bit lines coupled to the second memory cell, there is no need to add an additional transmission path, in other words, by multiplexing the data path in the present disclosure, the transmission path for information of redundantly replaced bit lines is added, but the manufacturing cost is not increased. In this way, the redundant replacement mechanism can be implemented without increasing the manufacturing cost under the condition that three semiconductor structures are stacked, thereby improving the utilization rate and the final yield of the semiconductor device.

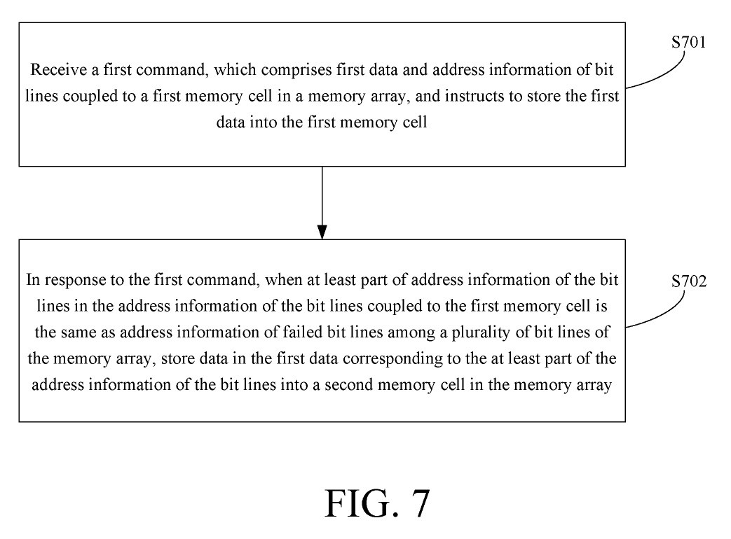

In a third aspect, an example of the present disclosure provides an operation method of a semiconductor device, referring to FIG. 7, FIG. 7 illustrates a schematic flowchart of an operation method of a semiconductor device, wherein the operation method comprises the following operations:

Operation S701: receiving a first command CMD1, which includes first data and address information of bit lines coupled to a first memory cell in a memory array, and instructs to store the first data into the first memory cell.

Operation S702: in response to the first command CMD1, when at least part of address information of the bit lines in the address information of bit lines coupled to the first memory cell is the same as address information of failed bit lines among a plurality of bit lines of the memory array, storing data in the first data corresponding to the at least part of the address information of the bit lines into a second memory cell in the memory array, wherein the semiconductor device comprises: a first semiconductor structure comprising the memory array and the plurality of bit lines coupled to the memory array; and a second semiconductor structure comprising a peripheral circuit coupled to the memory array.

In some examples, the method further comprises: when all the address information of the bit lines coupled to the first memory cell is the same as the address information of the failed bit lines, storing all the first data into the second memory cell; and when part of the address information of the bit lines coupled to the first memory cell is the same as the address information of the failed bit lines, storing second data in the first data corresponding to the part of the address information of the bit lines into the second memory cell and storing the remaining third data in the first data into the first memory cell.

In some examples, the method further comprises: receiving a second command instructing to read the first data; and feeding back address information of bit lines coupled to the second memory cell, the second data and the third data in response to the second command.

In some examples, the method further comprises: storing the address information of the failed bit lines and the address information of the bit lines coupled to the second memory cell into an addressing register of the peripheral circuit.

In some examples, the method further comprises: transmitting the first data through a data path in the peripheral circuit during the process of responding to the first command; and transmitting the address information of the bit lines coupled to the second memory cell, the second data and the third data through the data path during the process of responding to the second command.

In some examples, the method further comprises: generating a plurality of write clock signals and a plurality of data write signals by a read-write control circuit in the peripheral circuit in response to the first command; and generating a plurality of read clock signals and a plurality of data read signals by the read-write control circuit in response to the second command.

In some examples, the method further comprises: sequentially storing the second data into the second memory cell and the third data into the first memory cell by a data selection circuit in the peripheral circuit based on the plurality of write clock signals and the plurality of data write signals; and multiplexing the second data, the third data, and the address information of the failed bit lines onto the data path by the data selection circuit based on the plurality of read clock signals and the plurality of data read signals.

In some examples, the method further comprises: gating the second data to a transmission interface where the address information of the bit lines coupled to the second memory cell is outputted in beats by a redundancy control circuit in the peripheral circuit.

In some examples, the second semiconductor structure further comprises a connection structure extending through the memory array and connected to the peripheral circuit; and the method further comprises: transmitting the first command and the second command through the connection structure.

In some examples, the method further comprises: storing data into the first memory cell when the address information of the bit lines coupled to the first memory cell is different from the address information of the failed bit lines.

In some examples, the method further comprises: receiving and responding to a third command, testing the plurality of bit lines, and obtaining the address information of the failed bit lines.

The interface multiplexing between circuits in the read operation is described by way of example below in conjunction with the examples.

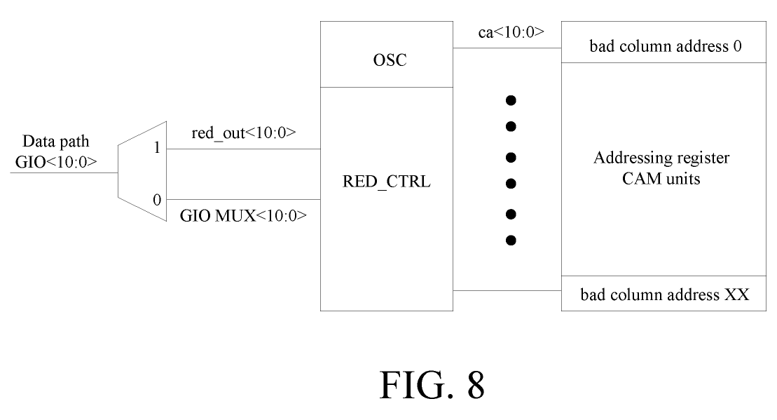

Referring to FIG. 8, FIG. 8 is a multiplexing logic block diagram of a data path in a semiconductor device. When the read operation is performed, it is assumed that data bus width of data path GIO (General Input/Output) is 32 bits, page size is 2 kilobytes (KB), and the number of entries stored in the addressing register is ca<10:0>. After the control circuit sends a read command (e.g., the second command CMD2) comprising redundancy repair information to the peripheral circuit, the peripheral circuit responds to the second command CMD2 and generates an enable control signal. Here, the second command CMD2 comprises a plane address where the target memory cell is located.

Based on a plurality of read clock signals (clk), address information of bit lines coupled to a second memory cell corresponding to a first failed bit line (bad column address 0) to a last failed bit line (bad column address XX) is sequentially gated to redundant transmission interface of the data path, for example, Red-out<10:0>, and then the data path can be multiplexed to feed back the information to the control circuit. In this way, when there are failed bit lines in the semiconductor device, transmission channel of address information of redundant bit lines can be increased through the above implementations, so that sharing and unification of redundancy repair mechanism between the control circuit and the peripheral circuit can be implemented, thereby improving multiplex rate of the semiconductor device.

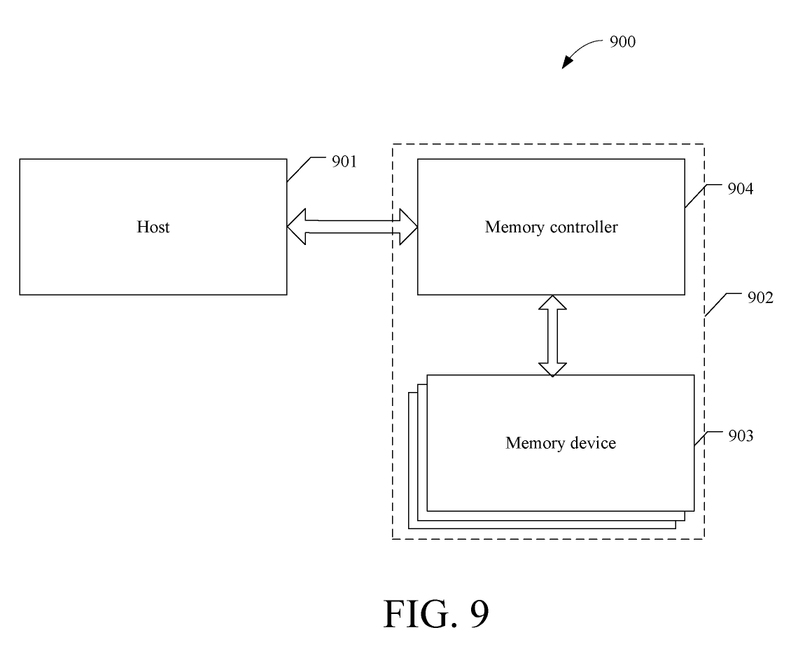

Based on the above semiconductor device, an example of the present disclosure provides an electronic device, FIG. 9 is a schematic diagram of an example electronic device having a semiconductor device provided by an example of the present disclosure. As shown in FIG. 9, an electronic device 900 comprises a semiconductor device 902 in any one of the above examples.

In some examples, as shown in FIG. 9, the electronic device 900 further comprises a host 901 coupled to the semiconductor device 902.

In the examples of the present disclosure, the electronic device 900 may be a mobile phone, a desktop computer, a laptop computer, a tablet computer, a vehicle computer, a game console, a printer, a positioning device, a wearable electronic device, an intelligent sensor, a virtual reality (VR) device, an augmented reality (AR) device, or any other suitable electronic device having a memory therein. As shown in FIG. 9, the electronic device 900 may comprise the host 901 and the semiconductor device 902, which may comprise one or more memory devices 903 and a memory controller 904. The host 901 may comprise a processor of the electronic device, such as a central 9rocessing unit (CPU), or a system on a chip (SoC), such as an application processor (AP). The host 901 may be configured to send data to or receive data from the semiconductor device 902. The memory device 903 comprises a memory array and a peripheral circuit coupled to the memory array. The memory controller 904 herein may comprise, for example, the control circuit in the above examples.

In some implementations, the memory controller 904 is coupled to the memory device 903 and the host 901 and is configured to control the memory device 903. The memory controller 904 may manage data stored in the memory device 903 and communicate with the host 901. In some implementations, the memory controller 904 is designed to operate in a low duty cycle environment like in a secure digital card, a compact flash card (CFC), a universal serial bus (USB) flash drive, or other medium used in electronic devices such as personal computers, digital cameras, mobile phones, etc. In other implementations, the memory controller 904 is designed to operate in a high duty cycle environment like a solid state drive or an embedded multi-media card (eMMC).

In some examples, the memory controller 904 and the one or more memory devices 903 may be integrated into various types of memory devices, that is, the semiconductor device 902 may be implemented and packaged into different types of terminal electronic products.

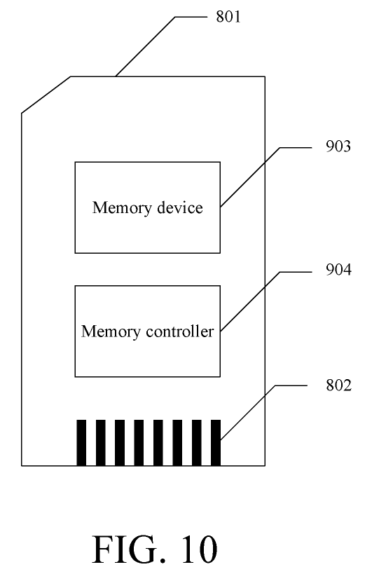

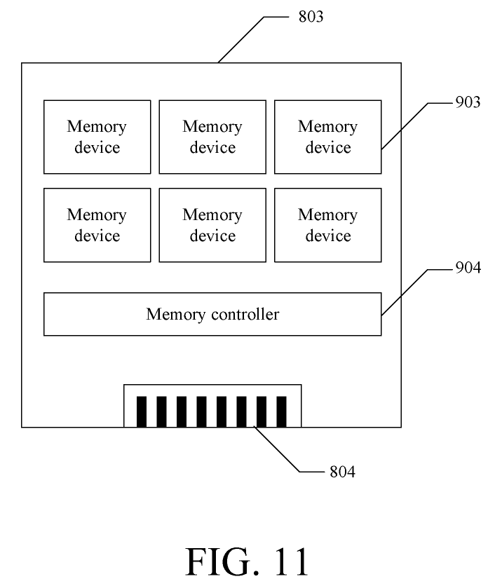

In one example as shown in FIG. 10, the memory controller 904 and a single memory device 903 may be integrated into the memory card 801. The memory card 801 may be one of a compact flash card, a smart media card (SMC), a memory stick (MS), a multi-media card (MMC), such as an reduced-size MMC (RS-MMC), an MMCmicro, an eMMC, etc., a secure digital card, such as a Mini SD card, a Micro SD card, an secure digital high capacity (SDHC) card, etc., and a universal flash card. The memory card 801 may further comprise a memory card connector 802 that couples the memory card 801 to a host-side device (e.g., the host 901 in FIG. 9). In another example as shown in FIG. 11, the memory controller 904 and a plurality of memory devices 903 may be integrated into SSD 803. SSD 803 may also comprise an SSD connector 804 that couples the SSD 803 to the host-side device (e.g., the host 901 in FIG. 9). In some implementations, the storage capacity and/or operating speed of the SSD 803 is greater than the storage capacity and/or operating speed of the memory card 801.

In some implementations, the memory controller 904 is designed operate in a low duty cycle environment like a secure digital (SD) card, a compact flash (CF) card, a universal serial bus (USB) flash drive, or other medium used in electronic devices such as personal computers, digital cameras, mobile phones, etc. In some implementations, the memory controller 904 is designed to operate in a high duty cycle environment solid state disk (SSD) or embedded multimedia card (eMMC) functioning as data storage for a mobile device such as a smartphone, a tablet computer, a laptop computer, etc., and an enterprise storage array.

The memory controller 904 may be configured to control operations of the memory device 903, such as read, erase, and program operations. The memory controller 904 may further be configured to manage various functions with respect to data stored or to be stored in the memory device 903, including, but not limited to, bad block management, garbage collection, logical-to-physical address translation, wear leveling, etc. In some implementations, the memory controller 904 is further configured to process error correction codes (ECC) with respect to data read from or written to the memory device 903. The memory controller 904 may also perform any other suitable functions, such as formatting the memory device 903. The memory controller 904 may communicate with an external device (e.g., the host 901) according to a particular communication protocol. For example, the memory device 903 may communicate with the external device through at least one of various interface protocols, such as a USB protocol, an MMC protocol, a peripheral component interconnect (PCI) protocol, a PCI-express (PCI-E) protocol, an advanced technology attachment (ATA) protocol, a serial ATA protocol, a parallel ATA protocol, a small computer small interface (SCSI) protocol, an enhanced small disk Interface (ESDI) protocol, an integrated drive electronics (IDE) protocol, a Firewire protocol, etc.

The memory controller 904 and the one or more memory devices 903 may be integrated into various types of memory apparatuses, for example, included in the same package (e.g., universal flash storage (UFS) package or eMMC package). That is, the semiconductor device 902 may be implemented and packaged into different types of terminal electronic products.

It should be understood that references to “some examples” or “examples of the present disclosure” throughout the specification mean that particular features, structures, or characteristics related to the example are included in at least one example of the present disclosure. Therefore, “in some examples” or “in examples of the present disclosure” appearing throughout the specification does not necessarily refer to the same example. In addition, the particular features, structures, or characteristics may be combined in one or more examples in any suitable manner. It should be understood that in the various examples of the present disclosure, the sequence numbers of the above processes do not imply the order of execution. The order of execution of each process should be determined by its function and internal logic, and should not impose any limitation on the implementation process of the examples of the present disclosure. The above sequence numbers of the examples of the present disclosure are merely for description and do not represent the superiority or inferiority of the examples.

In view of this, examples of the present disclosure provide a semiconductor device and an operation method thereof.

In a first aspect, an example of the present disclosure provides a semiconductor device, comprising: a first semiconductor structure comprising a memory array and a plurality of bit lines coupled to the memory array, wherein the memory array comprises a first memory cell and a second memory cell; and a second semiconductor structure comprising a peripheral circuit coupled to the memory array and configured to: receive a first command, which comprises first data and address information of bit lines coupled to the first memory cell, and instructs to store the first data into the first memory cell; and in response to the first command, when at least part of address information of the bit lines in the address information of the bit lines coupled to the first memory cell is the same as address information of failed bit lines among the plurality of bit lines, store data in the first data corresponding to the at least part of the address information of the bit lines into the second memory cell.

In some examples, the peripheral circuit is further configured to: when all the address information of the bit lines coupled to the first memory cell is the same as the address information of the failed bit lines, store all the first data into the second memory cell; and when part of the address information of the bit lines coupled to the first memory cell is the same as the address information of the failed bit lines, store second data in the first data corresponding to the part of the address information of the bit lines into the second memory cell, and store the remaining third data in the first data into the first memory cell.

In some examples, the peripheral circuit is further configured to: receive a second command instructing to read the first data; and feed back address information of bit lines coupled to the second memory cell, the second data, and the third data in response to the second command.

In some examples, the peripheral circuit further comprises an addressing register configured to store the address information of the failed bit lines and the address information of the bit lines coupled to the second memory cell.

In some examples, the peripheral circuit further comprises: a data path coupled to the addressing register and configured to: transmit the first data during the process of responding to the first command; and transmit the address information of the bit lines coupled to the second memory cell, the second data and the third data during the process of responding to the second command.

In some examples, when there are multiple entries of address information of the bit lines coupled to the second memory cell, the peripheral circuit further comprises: a read-write control circuit located between the addressing register and the data path and configured to: generate a plurality of write clock signals and a plurality of data write signals in response to the first command; and generate a plurality of read clock signals and a plurality of data read signals in response to the second command.

In some examples, the peripheral circuit further comprises a data selection circuit located between the data path and the read-write control circuit with the other end of the data selection circuit coupled to the memory array, wherein the data selection circuit is configured to: sequentially store the second data into the second memory cell and the third data into the first memory cell based on the plurality of write clock signals and the plurality of data write signals; and multiplex the second data, the third data and the address information of the failed bit lines onto the data path based on the plurality of read clock signals and the plurality of data read signals.

In some examples, the peripheral circuit further comprises a redundancy control circuit; the redundancy control circuit located between the data selection circuit and the memory array and configured to: gate the second data to a transmission interface coupled to the second memory cell in beats.

In some examples, the first semiconductor structure is bonded to the second semiconductor structure; the first semiconductor structure further comprises a connection structure extending through the memory array and connected to the peripheral circuit, wherein the connection structure is configured to transmit the first command and the second command.

In some examples, the peripheral circuit is further configured to receive and respond to a third command to test the plurality of bit lines to obtain the address information of the failed bit lines.

In some examples, the number of failed bit lines is less than or equal to the number of bit lines coupled to the second memory cell.

In some examples, the memory array comprises a plurality of NAND memory cells; the semiconductor device comprises a three-dimensional NAND type memory.

In a second aspect, an example of the present disclosure provides a semiconductor device, comprising: a first semiconductor structure comprising a memory array and a plurality of bit lines coupled to the memory array, wherein the memory array comprises a first memory cell and a second memory cell; a second semiconductor structure comprising a peripheral circuit coupled to the memory array; and a third semiconductor structure comprising a control circuit coupled to the peripheral circuit, wherein the control circuit is configured to send a first command, which comprises first data and address information of bit lines coupled to the first memory cell, and instructs to store the first data into the first memory cell; and the peripheral circuit is configured to: receive and respond to the first command; and when at least part of address information of the bit lines in the address information of the bit lines coupled to the first memory cell is the same as address information of failed bit lines among the plurality of bit lines, store data in the first data corresponding to the at least part of the address information of the bit lines into the second memory cell.

In some examples, the peripheral circuit is configured to: when all the address information of the bit lines coupled to the first memory cell is the same as the address information of the failed bit lines, store all the first data into the second memory cell; and when part of the address information of the bit lines coupled to the first memory cell is the same as the address information of the failed bit lines, store second data in the first data corresponding to the part of address information of the bit lines into the second memory cell, and store the remaining third data in the first data into the first memory cell.

In some examples, the control circuit is further configured to send a fourth command instructing to store the address information of the failed bit lines to an addressing register of the peripheral circuit; and the peripheral circuit is further configured to receive and respond to the fourth command to store the address information of the failed bit lines into the addressing register.

In some examples, the peripheral circuit is further configured to store the address information of the bit lines coupled to the second memory cell into the addressing register during the process of responding to the first command.

In some examples, the control circuit is further configured to send a second command instructing to obtain the first data; and the peripheral circuit is further configured to receive and respond to the second command to feed back the address information of the bit lines coupled to the second memory cell, the second data, and the third data to the control circuit.

In some examples, the control circuit is further configured to obtain the first data based on the address information of the bit lines coupled to the second memory cell, the second data, and the third data.

In some examples, the control circuit is further configured to send a third command instructing to test the plurality of bit lines; and the peripheral circuit is further configured to receive and respond to the third command to test the plurality of bit lines and obtain the address information of the failed bit lines.

In a third aspect, an example of the present disclosure provides an operation method of a semiconductor device, comprising: receiving a first command, which comprises first data and address information of bit lines coupled to a first memory cell in a memory array, and instructs to store the first data into the first memory cell; in response to the first command, when at least part of address information of the bit line in the address information of the bit lines coupled to the first memory cell is the same as address information of failed bit lines among a plurality of bit lines of the memory array, storing data in the first data corresponding to the at least part of the address information of the bit lines into a second memory cell in the memory array; wherein the semiconductor device comprises: a first semiconductor structure comprising the memory array and the plurality of bit lines coupled to the memory array; and a second semiconductor structure comprising a peripheral circuit coupled to the memory array.

In some examples, the method further comprises: when all the address information of the bit lines coupled to the first memory cell is the same as the address information of the failed bit lines, storing all the first data into the second memory cell; and when part of the address information of the bit lines coupled to the first memory cell is the same as the address information of the failed bit lines, storing second data in the first data corresponding to the part of address information of the bit lines into the second memory cell, and storing the remaining third data in the first data into the first memory cell.

In some examples, the method further comprises: receiving a second command instructing to read the first data; and feeding back address information of bit lines coupled to the second memory cell, the second data, and the third data in response to the second command.

In some examples, the method further comprises: storing the address information of the failed bit lines and the address information of the bit lines coupled to the second memory cell into an addressing register of the peripheral circuit.

In some examples, the method further comprises: transmitting the first data through a data path in the peripheral circuit during the process of responding to the first command; and transmitting the address information of the bit lines coupled to the second memory cell, the second data and the third data through the data path during the process of responding to the second command.

In some examples, the method further comprises: generating a plurality of write clock signals and a plurality of data write signals by a read-write control circuit in the peripheral circuit in response to the first command; and generating a plurality of read clock signals and a plurality of data read signals by the read-write control circuit in response to the second command.

In some examples, the method further comprises: sequentially storing the second data into the second memory cell and the third data into the first memory cell by a data selection circuit in the peripheral circuit based on the plurality of write clock signals and the plurality of data write signals; and multiplexing the second data, the third data, and the address information of the failed bit lines onto the data path by the data selection circuit based on the plurality of read clock signals and the plurality of data read signals.

In some examples, the method further comprises: gating the second data to a transmission interface coupled to the second memory cell in beats by a redundancy control circuit in the peripheral circuit.

In some examples, the second semiconductor structure further comprises a connection structure extending through the memory array and connected to the peripheral circuit; and the method further comprises: transmitting the first command and the second command by the connection structure.

In some examples, the method further comprises: receiving and respond to a third command to test the plurality of bit lines and obtain the address information of the failed bit lines.

In the examples of the present disclosure, the memory array and the plurality of bit lines are disposed in the first semiconductor structure, the first memory cell and the second memory cell are disposed in the memory array, the peripheral circuit is disposed in the second semiconductor structure, and the peripheral circuit is coupled to the memory array. In this case, when the peripheral circuit receives the first command and instructs to store first data into the first memory cell, the data in the first data corresponding to the failed bit lines is transferred to the second memory cell by judging whether the bit lines coupled to the first memory cell are failed bit lines or not, and when determining that there are failed bit lines among the bit lines coupled to the first memory cell. In this way, it will be instructed that at least part of the data stored in the first memory cell is transferred to the second memory cell through redundancy replacement mechanism when there are failed bit lines among the bit lines coupled to the first memory cell, so that the semiconductor structure with part of bit lines failed is continuously used, and the utilization rate and the final yield of the semiconductor device are improved.

The above descriptions are merely preferred implementations of the present disclosure, and not intended to limit the patent scope of the present disclosure. Equivalent structure transformation made by utilizing the contents of the specification and the drawings of the present disclosure under the inventive concept of the present disclosure, or direct/indirect application to other related technical fields are both encompassed within the patent protection scope of the present disclosure.

What is claimed is:

1. A semiconductor device, comprising:
a first semiconductor structure, comprising:
a memory array comprising a first memory cell and a second memory cell;
first bit lines coupled to the first memory cell;
second bit lines coupled to the second memory cell; and
a second semiconductor structure, comprising:
a peripheral circuit coupled to the memory array and configured to:
receive a first command, the first command to include first data and first address information of the first bit lines coupled to the first memory cell, and the first command to instruct to store the first data in the first memory cell; and
in response to the first command and in response to at least some of the first address information of the first bit lines corresponding to disabled bit lines, store a portion of the first data in the second memory cell, the portion of the first data corresponding to the at least some of the first address information of the first bit lines.

2. The semiconductor device according to claim 1, wherein the first data includes second data corresponding to the first address information and third data corresponding to second address information, the second address information corresponding to the second bit lines, wherein the peripheral circuit is configured to:
in response to part of all the first address information of the first bit lines coupled to the first memory cell corresponding to the disabled bit lines, store all the first data in the second memory cell; and
in response to the first address information of the first bit lines coupled to the first memory cell corresponding to the disabled bit lines, store the second data in the second memory cell, and store the third data in the first memory cell.

3. The semiconductor device according to claim 2, wherein the peripheral circuit is configured to:
receive a second command instructing to read the first data; and
feed back the second address information of the second bit lines coupled to the second memory cell, the second data and the third data in response to the second command.

4. The semiconductor device according to claim 3, wherein the peripheral circuit further comprises:
an addressing register configured to store the first address information of the disabled bit lines and the second address information of the second bit lines coupled to the second memory cell.

5. The semiconductor device according to claim 4, wherein the peripheral circuit further comprises:
a data path coupled to the addressing register and configured to:
transmit the first data during a process of responding to the first command; and
transmit the second address information of the second bit lines coupled to the second memory cell, the second data and the third data during a process of responding to the second command.

6. The semiconductor device according to claim 5, wherein, based on multiple entries of the second address information of the second bit lines being coupled to the second memory cell, the peripheral circuit further comprises:
a read-write control circuit located between the addressing register and the data path, wherein the read-write control circuit is configured to:
generate write clock signals and data write signals in response to the first command; and
generate read clock signals and data read signals in response to the second command.

7. The semiconductor device according to claim 6, wherein the peripheral circuit further comprises:
a data selection circuit located between the data path and the read-write control circuit, wherein the data selection circuit is coupled to the memory array, wherein the data selection circuit is configured to:
sequentially store the second data into the second memory cell and the third data into the first memory cell based on the write clock signals and the data write signals; and
multiplex the second data, the third data and the first address information of the disabled bit lines onto the data path based on the read clock signals and the data read signals.

8. The semiconductor device according to claim 7, wherein the peripheral circuit further comprises:
a redundancy control circuit located between the data selection circuit and the memory array, wherein the redundancy control circuit is configured to gate the second data to a transmission interface coupled to the second memory cell in beats.

9. The semiconductor device according to claim 8, wherein:
the first semiconductor structure is bonded to the second semiconductor structure; and
the first semiconductor structure further comprises a connection structure extending through the memory array and connected to the peripheral circuit, wherein the connection structure is configured to transmit the first command and the second command.

10. The semiconductor device according to claim 1, wherein the peripheral circuit is configured to:
receive and respond to a second command to test the first and second bit lines to obtain the at least some of the first address information of the disabled bit lines.

11. The semiconductor device of claim 1, wherein:
a number of the disabled bit lines is less than or equal to a number of the second bit lines coupled to the second memory cell.

12. The semiconductor device according to claim 1, wherein the memory array comprises NAND memory cells, and the semiconductor device comprises a three-dimensional NAND type memory.

13. A device, comprising:
a first semiconductor structure comprising:
a memory array comprising a first memory cell and a second memory cell;
first bit lines coupled to the first memory cell; and
second bit lines coupled to the second memory cell;
a second semiconductor structure comprising a peripheral circuit coupled to the memory array; and
a third semiconductor structure comprising a control circuit coupled to the peripheral circuit,
wherein the control circuit is configured to:
send a first command, the first command including first data and first address information of the first bit lines coupled to the first memory cell, and the first command to instruct to store the first data in the first memory cell; and
the peripheral circuit is configured to:
respond to the first command; and
in response to at least some of the first address information of the first bit lines corresponding to disabled bit lines, store a portion of the first data in the second memory cell, the portion of the first data corresponding to the at least some of the first address information of the first bit lines.

14. The device according to claim 13, wherein the first data includes second data corresponding to the first address information and third data corresponding to second address information, the second address information corresponding to the second bit lines, wherein the peripheral circuit is configured to:
in response to all the first address information of the first bit lines coupled to the first memory cell corresponding to the disabled bit lines, store all the first data in the second memory cell; and
in response to part of the first address information of the first bit lines coupled to the first memory cell corresponding to the disabled bit lines, store the second data in the second memory cell, and store the third data in the first memory cell.

15. The device according to claim 14, wherein:
the control circuit is configured to send a second command to instruct to store the first address information of the disabled bit lines to an addressing register of the peripheral circuit; and
the peripheral circuit is configured to receive and respond to the second command to store the first address information of the disabled bit lines in the addressing register.

16. The device according to claim 15, wherein:
the peripheral circuit is configured to store the second address information of the second bit lines coupled to the second memory cell to the addressing register during a process of responding to the first command.

17. The device according to claim 16, wherein:
the control circuit is configured to send a third command to instruct to obtain the first data; and
the peripheral circuit is configured to:
receive and respond to the third command to feed back the second address information of the second bit lines coupled to the second memory cell, the second data and the third data to the control circuit.

18. The device according to claim 17, wherein
the control circuit is configured to obtain the first data based on the second address information of the second bit lines coupled to the second memory cell, the second data and the third data.

19. The device according to claim 18, wherein
the control circuit is configured to send a fourth command to instruct to test the first and second bit lines; and
the peripheral circuit is configured to receive and respond to the fourth command to test the first and second bit lines and obtain the first address information of the disabled bit lines.

20. A method comprising:
receiving a first command, the first command including first data and first address information of first bit lines coupled to a first memory cell in a memory array of a first semiconductor structure, and the first command instructing to store the first data in the first memory cell; and
in response to the first command and in response to at least some of the first address information corresponding to disabled bit lines, storing a portion of the first data in a second memory cell in the memory array, the portion of the first data corresponding to the at least some of the first address information.
